(19) United States
(12) Patent Application Publication
(10) Pub. No.: US 2004/0091792 A1
(43) Pub. Date: May 13, 2004

(54) Phase edge phase shift mask and method for fabricating the same

(76) Inventors: Myung-Ah Kang, Busan-City (KR); In-Kyun Shin, Yongin-City (KR)

Correspondence Address: VOLENTINE FRANCOS, P.L.L.C., Suite 150, 12200 Sunrise Valley Drive, Reston, VA, 20191, US

(21) Appl. No.: 10/608,639

(22) Filed: Jun. 30, 2003

(30) Foreign Application Priority Data
Nov. 11, 2002 (KR) 2002-69665

(51) Int. Cl. G03F 9/00; G03C 5/00

(52) U.S. Cl. 430/5; 430/322; 430/323; 430/324

(57) ABSTRACT

A phase edge phase shift mask is capable of providing photoresist patterns having a variety of sizes and pitches. The phase edge phase shift mask is formed from a quartz substrate. The substrate is etched to provide a trench therein of a depth that will induce a 180° phase shift in exposure light. An auxiliary pattern is formed on a portion of the top of the quartz substrate and/or on a portion of the substrate at the bottom of the trench as spaced from the sidewall surface of the substrate that defines the sides of the trench. The auxiliary pattern is formed of either an optical interference material or an opaque material.

### BACKGROUND OF THE INVENTION

1. Field of the Invention

The present invention relates to a phase edge phase shift mask (hereinafter referred to as a “PEPSM”) and to a method of fabricating the same.

2. Description of the Related Art

The demand for increasing the integration density of semiconductor devices has led to the marked development of a photolithographic process for forming fine patterns. The photolithographic process begins by coating a wafer with a photoresist, and then exposing the photoresist to light of a given wavelength. The exposed layer of photoresist is then developed to pattern the photoresist. The size (line width) or the resolution of the photoresist pattern can be determined using the known Rayleigh equation. According to the equation, the minimum critical dimension is proportional to the wavelength of the exposure light and inversely proportional to the numerical aperture of a projection lens by which the exposure light is projected onto the photoresist. However, diffraction will occur if the desired line width of a photoresist pattern is smaller than the wavelength of an exposure source, whereupon an aerial image will be generated.

Phase shift masks (hereinafter referred to as a “PSMs”) have been proposed as means for preventing such a phenomenon. Unlike binary masks that adjust the amplitude of the exposure light, PSMs adjust the phase of the exposure light using destructive interference, thereby alleviating the diffraction of the light. A PSM can be categorized as either an attenuated PSM having a 180° phase shift region (hereinafter, “180° region”) formed on a substrate by a phase shift layer or an alternating PSM having a 180° region formed in a substrate by a trench. The PEPSM—a later embodiment of the alternating PSM—modulates the phase of the exposure light at an etched facet of a substrate without the use of an opaque layer.

FIGS. 1(a)-1(d) represent a typical PEPSM, wherein FIG. 1(a) is a cross-sectional view of the PEPSM, FIG. 1(b) is a graph of an electromagnetic field on a mask, FIG. 1(c) is a graph of an electromagnetic field on a wafer, and FIG.1(d) is a graph of the optical intensity on the wafer.

Referring to FIG. 1(a), the PEPSM 10 is formed of a quartz substrate 11 in which a trench 15 is formed. The trench 15 is formed by anisotropically etching a predetermined portion of the quartz substrate 10. In the PEPSM 10, the region where the trench 15 is formed is a 180° region, while the region of the quartz substrate 11 where the trench 15 is not formed is a 0° region.

If light is directed through the PEPSM 10, the light experiences a phase shift at a sidewall of the trench 15 of the PEPSM 10 as shown in FIG. 1(b), and the phase shift is less pronounced at the wafer than at the PEPSM 10 as shown in FIG. 1(c). Meanwhile, as illustrated in FIG. 1(d), the optical intensity of the exposure light on the wafer is decreased at a region (A) where a pattern is formed, region (A) corresponding to the sidewall of the trench 15 of the PEPSM 10. The width of the region (A) can be made very fine using the PEPSM, i.e., a photoresist pattern having a fine line width can be produced using the PEPSM. Accordingly, fine patterns such as a gate electrode can be formed using the photoresist pattern as an etch mask.

Although the PEPSM provides excellent resolution, it can be used to produce only photoresist patterns whose line width has a fixed pitch and size. Accordingly, the PEPSM is not suitable for use in a variety of processes.

Accordingly, as illustrated in FIG. 2, a technique of forming an auxiliary pattern 18 at the edge of the 0° region of a PEPSM 20 was proposed so that the PEPSM 20 could form patterns of various pitches and sizes unlike the conventional PEPSM 10. The auxiliary pattern 18 is formed of an opaque material such as chromium. The width of the auxiliary pattern 18 is determined in consideration of the desired size and pitch of the photoresist pattern. The auxiliary pattern 18 is to have a width of approximately 70 nm to 90 nm when the PEPSM 20 is used in a process of forming a gate electrode. It is Important that the auxiliary pattern 18 coincide with the sidewall of the trench 15. This makes it easy to produce a photoresist pattern having the desired line width because the patterning of the photoresist is to take place at a region corresponding to the sidewall of the trench 15.

However, forming the auxiliary pattern 18 at the sidewall of the trench 15 requires a very intricate and exact alignment process.

Furthermore, the deeper the trench 15, the more difficult it is to anisotropically form the sidewall of the trench 15. In the case of a PEPSM 20 having a relatively deep trench 15, the auxiliary pattern 18 can be damaged due to an unstable base provided by the underlying structure, i.e., the underlying surface of the quartz substrate 11.

### SUMMARY OF THE INVENTION

Accordingly, an object of the present invention is to provide PEPSMs by which photoresist patterns having a variety of sizes and pitches can be produced.

Another object of the present invention is to provide a relatively simple and easy method for fabricating a PEPSM.

In accordance with one aspect of the present invention, a PEPSM is formed of a transparent substrate (e.g., a quartz substrate), and an auxiliary pattern. The substrate has a top surface beneath which a trench constituting a 180° phase shift region is defined, a sidewall surface defining the sides of the trench, and a bottom surface defining the bottom of the trench. The auxiliary pattern is disposed on at least one of the top and bottom surfaces of the substrate as spaced laterally from the sidewall surface.

In accordance with yet another aspect of the present invention, there is provided a method for fabricating a PEPSM, comprising providing a transparent substrate (e.g., a quartz substrate), etching the quartz substrate to form a trench in the substrate, forming a layer of material on the substrate at the side thereof in which the trench is formed, and etching the layer of material to form an auxiliary pattern therefrom on at least one of top and bottom surfaces of the substrate as spaced laterally from the sidewall surface of the substrate that defines the sides of the trench.

The auxiliary pattern may be formed of an optical interference material or an opaque material such as chromium. Also, the auxiliary pattern is formed to have such a line width that the patterning of a photoresist layer will not occur at a region corresponding to the auxiliary pattern during an exposure and development process. For example, the auxiliary pattern is formed to have a line width of 30 nm to 200 nm.

### BRIEF DESCRIPTION OF THE DRAWINGS

The above and other objects, features and advantages of the present invention will become more apparent from the following detailed description of the preferred embodiments thereof made with reference to the attached drawings, in which:

FIG. 1(a) is a cross-sectional view of a conventional PEPSM;

FIG. 1(b) is a graph of an electromagnetic field of exposure light directed onto the conventional PEPSM;

FIG. 1(c) is a graph of an electromagnetic field on a wafer exposed to light directed through the conventional PESM;

FIG. 1(d) is a graph of the intensity of the exposure light on the wafer;

FIG. 2 is a cross-sectional view of another type of a conventional PEPSM;

FIG. 3(A) is a cross-sectional view of a PEPSM according to the present invention;

FIG. 3(B) is a graph of optical characteristics of the PEPSM according to the present invention;

FIG. 4 is a graph showing the line width of a photoresist pattern with respect to the line width of an auxiliary pattern of the PEPSM according to the present invention; and

FIGS. 5A through 5C are cross-sectional views of the PEPSM during its manufacture and thus collectively illustrate a method of fabricating the PEPSM according to the present invention.

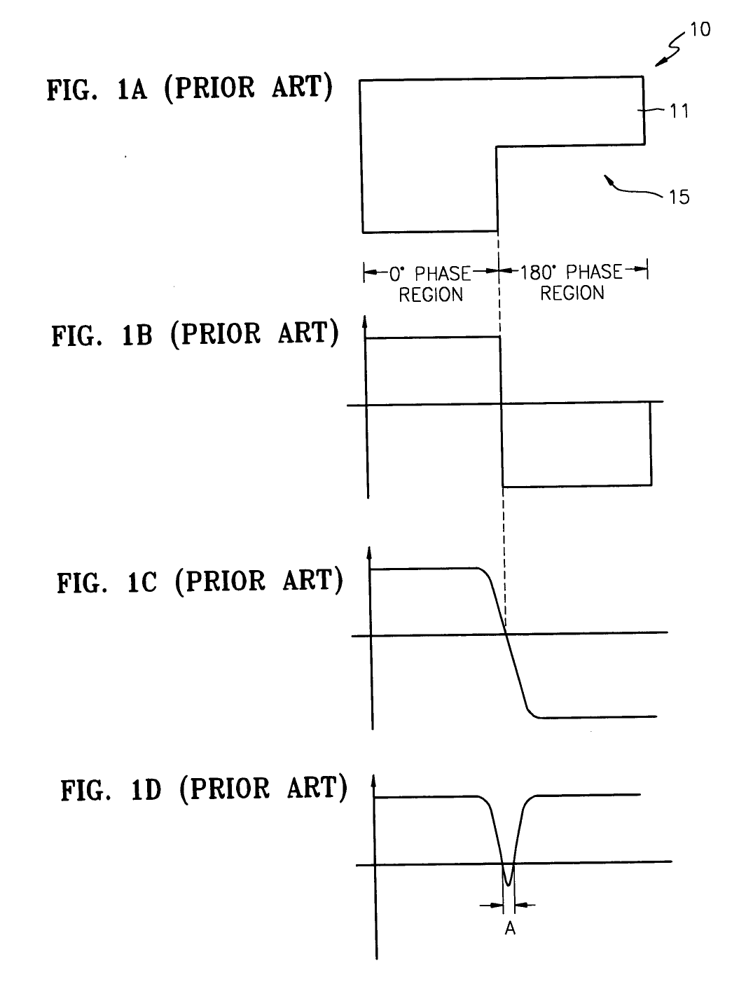

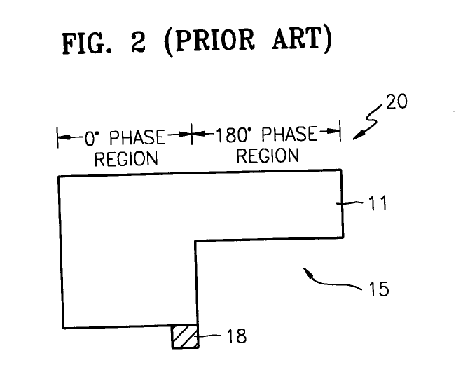

### DETAILED DESCRIPTION OF THE PREFERRED EMBODIMENTS

The present invention will now be described more fully with reference to the accompanying drawings, in which preferred embodiments of the invention are shown. In the drawings, the shape of elements is exaggerated for clarity, and the same reference numerals are used to designate the same elements throughout the drawings.

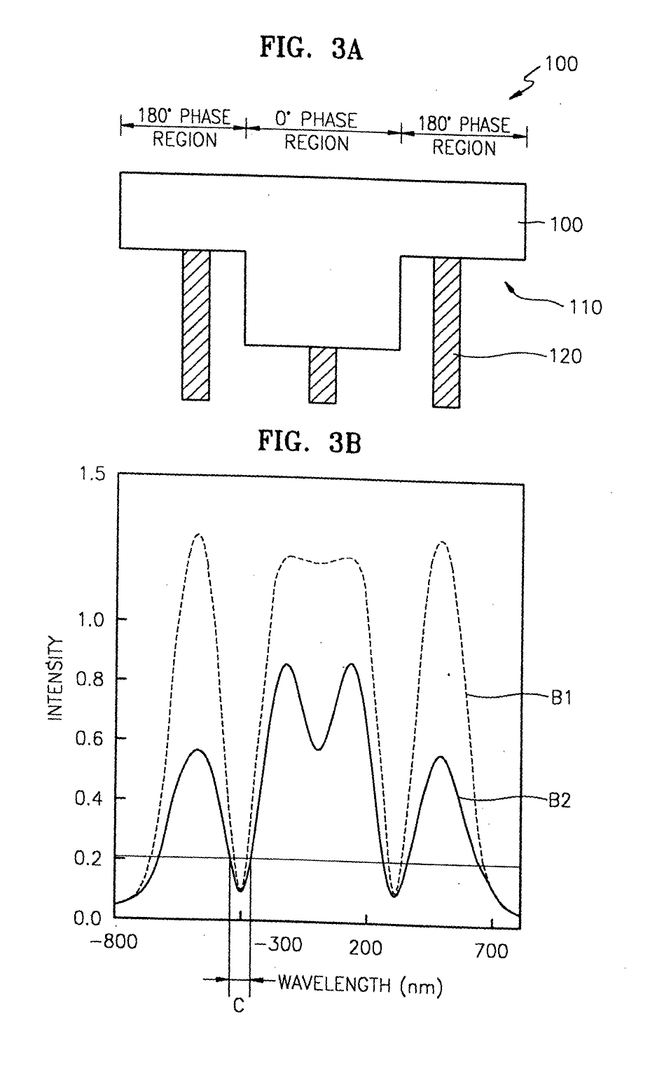

Referring first to FIG. 3A, a PEPSM 100 of the present invention includes a quartz substrate 100 having a trench 110. The trench 110 has such a depth as to shift the phase of incident light by 180°. Thus, a region where the trench 110 is formed is a 180° phase shift region (hereinafter, “180° region”), while the region of the quartz substrate 100 where the trench 110 is not formed is a 0° region. An auxiliary pattern is formed at predetermined portions of the 0° region and 180° region. The auxiliary pattern 120 may be formed on a planar surface as spaced laterally from the edge of the trench 110, for example, at the center of the 0° region and/or at the center of the bottom of the trench 110. The auxiliary pattern 120 may be formed of an optical interference material or an opaque material of, for example, chromium. Here, the line width and exposure conditions should be designed for so that the patterning of the photoresist will not occur at a region corresponding to the auxiliary pattern 120. In the present embodiment, the auxiliary pattern 120 is set to have a line width of 30 nm to 200 nm, for example.

The optical characteristics of the PEPSM 100 of the present invention is shown in FIG. 3B. In FIG. 3B, curve B1 shows the optical intensity of the PEPSM before the auxiliary pattern 120 is formed, whereas curve B2 shows the optical intensity measured when the auxiliary pattern 120 is present. FIG. 3B thus shows that the presence of the auxiliary pattern 120 reduces the amplitude of the optical intensity provided by the PEPSM 100. This is because the auxiliary pattern 120 causes optical interference. A decrease in the optical intensity changes the slope of the intensity curve. Thus, the intervals between regions where the photoresist will be patterned, i.e., regions C corresponding to sidewalls of the trench, is changed by the presence of the auxiliary pattern 120. Thus, the auxiliary pattern 120 can be used to provide a photoresist pattern of a desired line width.

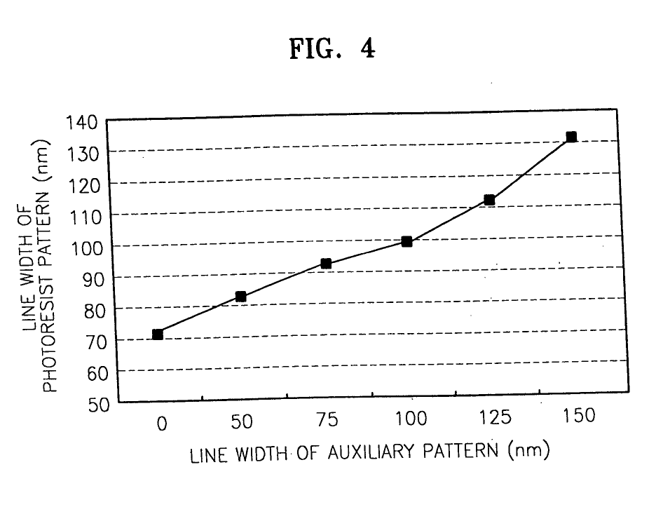

Referring to FIG. 4, the greater the line width of the auxiliary pattern 120, the greater the line width of the photoresist pattern becomes. More specifically, in the present embodiment, every increase of 25 nm in the line width of the auxiliary pattern 120 may produce an increase of 10 nm in the line width of the photoresist pattern. These results were achieved under the following exposure conditions: the numerical aperture (NA) of the exposure apparatus was set to 0.6, and the radius σ of light transmission of the aperture was set to 0.417. The exposure conditions were also set so that the photoresist was not patterned at locations corresponding to the auxiliary pattern 120.

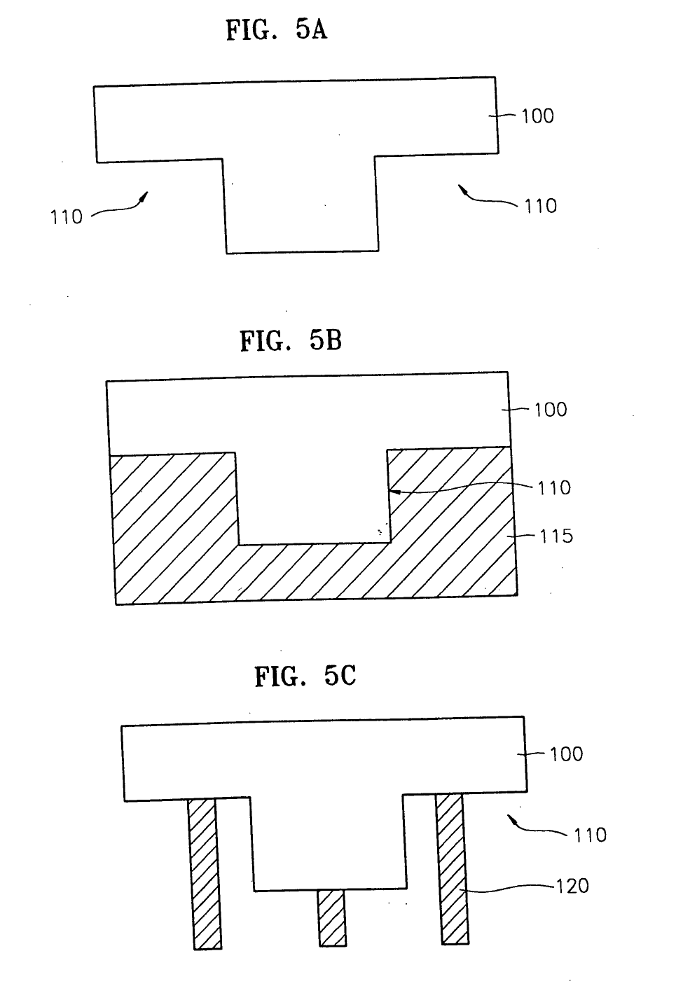

Hereinafter, a method of fabricating the PEPSM according to the present invention will be described with reference to FIGS. 5A through 5C.

Referring to FIG. 5A, a quartz substrate 100 is prepared as follows. A shield layer (not shown) is formed on a quartz plate such that a predetermined portion of the quartz plate is exposed. The exposed portion of the quartz plate is anisotropically etched to a predetermined depth to form a trench 110 therein. The depth of the trench 110 is designed for so as to shift the phase of light by 180° during an exposure process in which exposure light of a given wavelength is directed through the mask. The shield layer is then removed by a known method.

Referring to FIG. 5B, an opaque material, such as chromium, is formed to a predetermined thickness on the surface of the quartz substrate 100 in which the trench 110 has been formed. The resulting chromium layer 115 is thick enough to fill the trench 110.

Next, as shown in FIG. 5C, the chromium layer 115 is etched to form an auxiliary pattern 120 at the center of the quartz substrate 100 (where no trench is formed) and/or at the center of the surface defining the bottom of the trench 110. The margin for the alignment process is relatively great because the sidewall of the auxiliary pattern 120 is not required to coincide with that of the trench 110. In addition, the auxiliary pattern 120 is not likely to be damaged because the auxiliary pattern 120 is formed at a stable planar surface, i.e., at the center of the top surface of the quartz substrate or at the center of the surface defining the bottom of the trench.

According to the present invention as described above, a PEPSM having a trench comprises an auxiliary pattern having a predetermined line width at the center of the bottom of the trench and/or at the center-of a quartz substrate. The auxiliary pattern adjusts the intensity of incident light, thereby affecting the line width of a photoresist pattern. Therefore, photoresist patterns having a variety of pitches and sizes can be fabricated by using auxiliary patterns having different line widths. Furthermore, not only can the auxiliary pattern be fabricated using a simple alignment and manufacturing process, but also the risk of the auxiliary pattern becoming damage is small because the risks is formed on a stable planar surface.

Finally, although, the present invention has been particularly shown and described with respect to the preferred embodiments thereof, it will be understood by those of ordinary skill in the art that various changes in form and details may be made thereto without departing from the true spirit and scope of the present invention as defined by the following claims.

What is claimed is:

1. A phase edge phase shift mask comprising:
a transparent substrate having a top surface beneath which a trench constituting a 180° phase shift region is defined, a sidewall surface extending from said top surface and defining the sides of the trench, and a bottom surface extending from said sidewall surface and defining the bottom of the trench; and
an auxiliary pattern disposed on at least one of said top and bottom surfaces of said substrate as spaced laterally along said at least one of the top and bottom surfaces from said sidewall surface defining the sides of the trench.

2. The mask as claimed in claim 1, wherein the auxiliary pattern is disposed on at least one of a central portion of the top surface of the quartz substrate and a central portion of the bottom surface defining the bottom of the trench.

3. The mask as claimed in claim 1, wherein the auxiliary pattern is of an optical interference material.

4. The mask as claimed in claim 1, wherein the auxiliary pattern is of an opaque material.

5. The mask as claimed in claim 5, wherein the auxiliary pattern is of chromium.

6. The mask as claimed in claim 1, wherein the auxiliary pattern has a line width of 30 nm to 200 nm.

7. A method of fabricating a phase edge phase shift mask, the method comprising:
providing a transparent substrate;
etching the quartz substrate to form a trench in the substrate, the trench being situated beneath a top surface of the substrate and having sides defined by a sidewall surface of the substrate and a bottom defined by a bottom surface of the substrate;
forming a layer of material on the substrate at the side thereof in which the trench is formed; and
etching the layer of material to form an auxiliary pattern therefrom on at least one of said top and bottom surfaces of said substrate as spaced laterally along said at least one of the top and bottom surfaces from said sidewall surface defining the sides of the trench.

8. The method as claimed in claim 7, wherein said forming a layer of material on the substrate comprises forming a layer of an optical interference material on the substrate.

9. The method as claimed in claim 7, wherein said forming a layer of material on the substrate comprises forming a layer of an opaque material on the substrate.

10. The method as claimed in claim 9, wherein the opaque material is chromium.

11. The method as claimed in claim 7, wherein said etching a portion of the material comprises forming an auxiliary pattern having a line width of 30 nm to 200 nm on at least one of said top and bottom surfaces of said substrate as spaced laterally along said at least one of the top and bottom surfaces from said sidewall surface defining the sides of the trench.
